(19) United States
(12) Patent Application Publication
(10) Pub. No.: US 2026/0367196 A1
(43) Pub. Date: Nov. 19, 2026

(54) MAGNETIC SENSOR

(71) Applicant: HAECHITECH CORPORATION, Cheongju-si, Chungcheongbuk-do (KR)

(72) Inventors: Seong Min CHOE, Seongnam-si, Gyeonggi-do (KR); Joon Yul YUN, Seoul (KR)

(73) Assignee: HAECHITECH CORPORATION, Cheongju-si, Chungcheongbuk-do (KR)

(21) Appl. No.: 19/158,769

(22) PCT Filed: Apr. 19, 2024
(86) PCT No.: PCT/KR2024/005371

§ 371 Date: Aug. 21, 2025

(30) Foreign Application Priority Data
Apr. 20, 2023 (KR) 10-2023-0051869

(51) Int. Cl. G01R 33/07; G01R 19/10; G01R 19/25; G01R 19/32; G01R 33/00

(52) U.S. Cl. CPC G01R 33/07; G01R 19/10; G01R 19/25; G01R 19/32; G01R 33/0082

(57) ABSTRACT

The present invention proposes a magnetic sensor which can utilize, among Hall elements for detection included in a Hall sensor, a Hall element not used for detection to generate a reference voltage for temperature compensation so as to compensate for temperature dependence of the Hall electromotive force. The magnetic sensor includes: a Hall driving part for sequentially activating embedded multiple Hall elements to generate a detection voltage; an amplifier; an AD converter; and a reference voltage generation circuit.

### CROSS-REFERENCE TO RELATED APPLICATIONS

The present application claims priority of Korean Patent Application No. 10-2023-0051869 filed on Apr. 20, 2023, and is a U.S. national phase application of International Application No. PCT/KR 2024/005371, filed on Apr. 19, 2024, the entire contents of which are incorporated herein for all purposes by this reference.

### BACKGROUND OF THE DISCLOSURE

### FIELD OF THE DISCLOSURE

The present invention relates to a magnetic sensor, and more particularly, to a magnetic sensor capable of minimizing temperature-induced errors in Hall elements involved in magnetic sensing by generating and utilizing a reference voltage for temperature compensation using a Hall element that is separate from the Hall elements involved in magnetic sensing among multiple Hall elements.

### DESCRIPTION OF THE RELATED ART

A magnetic sensor uses a Hall element or a magnetoresistive element to convert the intensity of a magnetic field into a corresponding electrical quantity. Among these elements, the Hall element may be implemented as a thin, elongated conductor plate through which a constant current flows in one direction, for example, in the x-axis direction. If a magnetic field is applied to the conductor plate in the perpendicular direction, namely the z-axis direction, the Hall element is an element that utilizes a Hall effect, in which an electromotive force is generated in the y-axis direction that is perpendicular to both the magnetic field and current directions.

FIG. 1 shows an equivalent circuit of a conventional Hall element.

Referring to FIG. 1, a conventional Hall element has a bridge (Wheatstone bridge) shape formed by a combination of resistors. A resistor has a characteristic in which resistance changes with temperature. In particular, since pattern mismatches occur due to errors in the alignment process and etching operation during semiconductor manufacturing for fabricating Hall elements, the resistance of each resistor has a certain difference from a design target.

Due to pattern mismatches that exist from the time of Hall element fabrication, there is a limitation that an output voltage is generated due to differences in current flowing through each resistor even when no external magnetic field is applied. In particular, since temperature changes cause changes in resistance, the temperature changes induce changes in the output voltage, and these changed voltages are included in the output voltage as offset voltages, ultimately causing problems in accurately measuring the magnetic field quantity.

### SUMMARY OF THE DISCLOSURE

### Technical Problem

Technical problems to be solved by the present invention are directed to providing a magnetic sensor which can utilize, among Hall elements for detection included in a Hall sensor, a Hall element not used for detection to generate a reference voltage for temperature compensation so as to compensate for temperature dependence of the Hall electromotive force.

### Solution to Problem

The magnetic sensor according to the present invention for achieving the above technical problem includes a Hall driving part, an amplifier, an AD converter, and a reference voltage generation circuit.

The Hall driving part includes a first-type Hall element module configured to generate two detection voltages corresponding to a direction and magnitude of magnetism (hereinafter referred to as magnetic intensity) measured in response to a magnetic detection control signal and a temperature compensation control signal and to generate an auxiliary voltage for temperature compensation in response to the temperature compensation control signal, and a second-type Hall element module configured to generate two detection voltages corresponding to the measured magnetic intensity. The amplifier is configured to amplify a difference between the two detection voltages. The AD converter is configured to convert an analog differential amplified detection voltage, amplified by the amplifier, into a digital signal using a reference voltage for temperature compensation. The reference voltage generation circuit generates the reference voltage for temperature compensation using the auxiliary voltage for temperature compensation.

### ADVANTAGEOUS EFFECTS OF INVENTION

The magnetic sensor according to the present invention as described above uses other non-activated Hall elements as replica Hall elements when sequentially activating multiple Hall elements to detect magnetic intensity, thereby minimizing the area in which the magnetic sensor is implemented and minimizing the temperature dependence of the Hall electromotive force.

### BRIEF DESCRIPTION OF THE DRAWINGS

FIG. 1 illustrates an equivalent circuit of a conventional Hall element.

FIG. 2 is an embodiment of a magnetic sensor according to the present invention.

FIG. 3 is an embodiment of a Hall driving part according to the present invention.

FIGS. 4A to 4C illustrate an embodiment of a first type (TYPE I) of a Hall element module.

FIGS. 5A to 5C illustrate an embodiment of a second type (TYPE II) of a Hall element module.

FIG. 6 is an embodiment of a selection unit shown in FIGS. 4 and 5.

FIG. 7 is an embodiment of a reference voltage generation circuit.

FIG. 8 is a timing diagram of control signals applied to a magnetic sensor according to the present invention.

FIGS. 9A and 9B illustrate a configuration and magnetic sensing process of a magnetic sensor according to the present invention, which includes Hall element modules, each including two Hall elements.

FIGS. 10A and 10B are an example of a Hall element module used in a sensing process of a magnetic sensor and in a generation process of a temperature compensation voltage.

### DETAILED DESCRIPTION OF THE DISCLOSURE

To fully understand the present invention, advantages in operation of the present invention, and the objectives achieved by carrying out the present invention, reference should be made to the accompanying drawings that illustrate exemplary embodiments of the present invention and contents described in the accompanying drawings.

The present invention will be described in detail by describing preferred embodiments of the present invention with reference to the accompanying drawings below. Like reference numerals indicated in the respective drawings refer to like components.

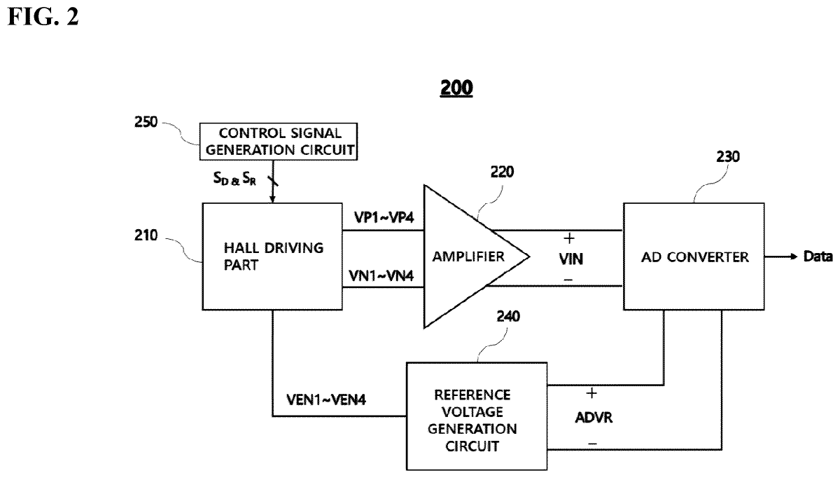

FIG. 2 is an embodiment of a magnetic sensor according to the present invention.

Referring to FIG. 2, a magnetic sensor 200 according to the present invention includes a Hall driving part 210, an amplifier 220, an AD converter 230, a reference voltage generation circuit 240, and a control signal generation circuit 250.

The Hall driving part 210, in response to a magnetic detection control signal SD and a temperature compensation control signal SR, on one hand generates detection voltages VP1 to VP4 and VN1 to VN4 corresponding to the direction and magnitude of magnetism (hereinafter referred to as magnetic intensity) around the Hall driving part 210, and on the other hand generates auxiliary voltages for temperature compensation VEN1 to VEN4.

The amplifier 220 amplifies the difference of detection voltages VP1 to VP4 and VN1 to VN4 output from the Hall driving part 210.

The AD converter 230 converts an analog differential amplified detection voltage VIN, amplified by the amplifier 220, into a digital signal (Data) using a reference voltage for temperature compensation ADVR.

The reference voltage generation circuit 240 generates the reference voltage for temperature compensation ADVR using the auxiliary voltages for temperature compensation VEN1 to VEN4 received from the Hall driving part 210.

The control signal generation circuit 250 generates the magnetic detection control signal SD and the temperature compensation control signal SR to control an operation of the Hall driving part 210.

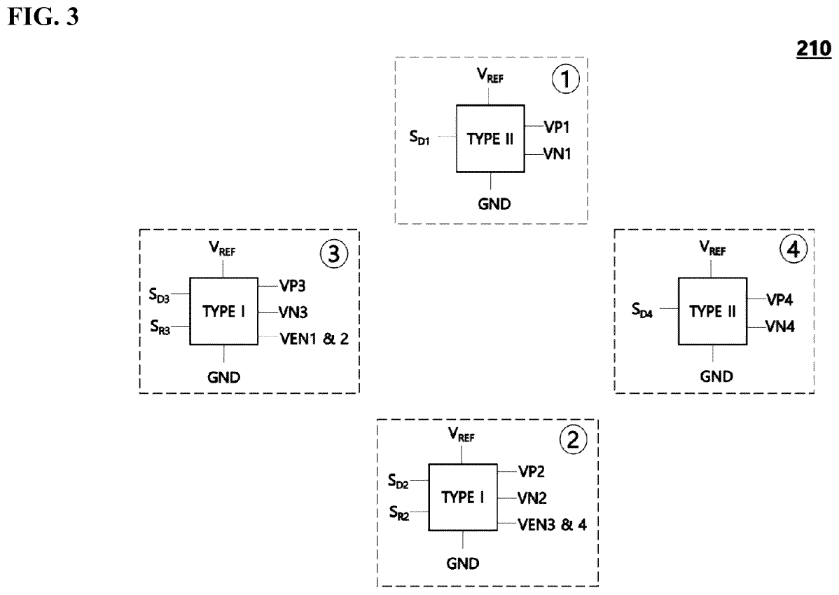

FIG. 3 is an embodiment of a Hall driving part according to the present invention.

Referring to FIG. 3, the Hall driving part 210 includes four Hall element modules \textcircled{1}, \textcircled{2}, \textcircled{3}, and \textcircled{4}. The four Hall element modules \textcircled{1}, \textcircled{2}, \textcircled{3}, and \textcircled{4} may be classified into two types (TYPE I and TYPE II).

The Hall driving part according to the present invention provides detecting the magnetic field by sequentially activating the four Hall element modules from a first Hall element module \textcircled{1} to a fourth Hall element module \textcircled{4}, rather than activating all the four Hall element modules simultaneously.

Accordingly, when one Hall element module is activated to detect magnetic intensity, the remaining three Hall element modules remain in an inactive state. In the present invention, it is provided that during magnetic intensity detection using one Hall element module, one of the remaining three inactive Hall element modules is used to generate auxiliary voltages for temperature compensation VEN1 to VEN4, which are used to generate the reference voltage for temperature compensation ADVR.

For example, when the first Hall element module \textcircled{1} and a second Hall element module \textcircled{2} are activated to detect magnetic intensity, a third Hall element module \textcircled{3}, which is in an inactive state, is utilized to generate auxiliary voltages for temperature compensation. When the third Hall element module \textcircled{3} and the fourth Hall element module \textcircled{4} are activated to detect magnetic intensity, the second Hall element module \textcircled{2}, which is in an inactive state, is utilized to generate auxiliary voltages for temperature compensation.

Among the four Hall element modules constituting the Hall driving part 210 according to the present invention, two arbitrarily selected element modules are configured to perform the functions of detecting magnetic intensity and generating an auxiliary voltage for temperature compensation, and the remaining two element modules are configured to perform only the function of detecting magnetic intensity.

It is assumed that a Hall element module that inherently performs the functions of detecting an external magnetic field and generating an auxiliary voltage for temperature compensation is referred to as a first type (TYPE I), and a Hall element module that performs only the function of detecting magnetic intensity is referred to as a second type (TYPE II), and the description will be provided accordingly.

An installation position of each of the two types of Hall element modules shown in FIG. 3 is merely an embodiment, and the installation positions of the two types of Hall element modules may be variously selected depending on the field of application.

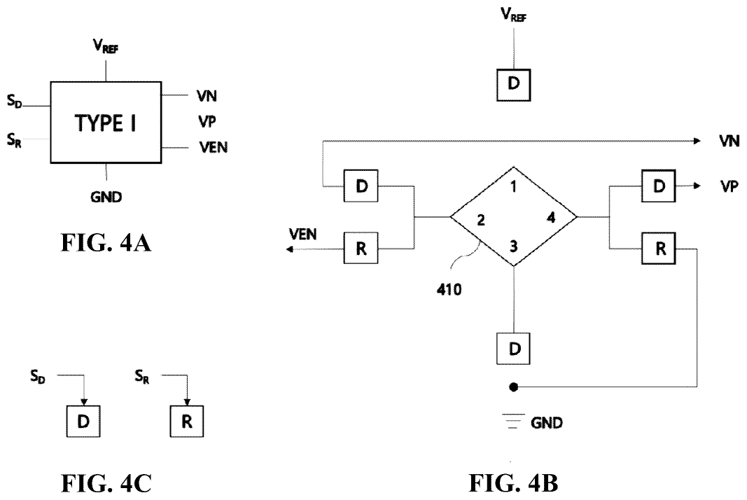

FIGS. 4A to 4C illustrate an embodiment of the first type (TYPE I) of a Hall element module.

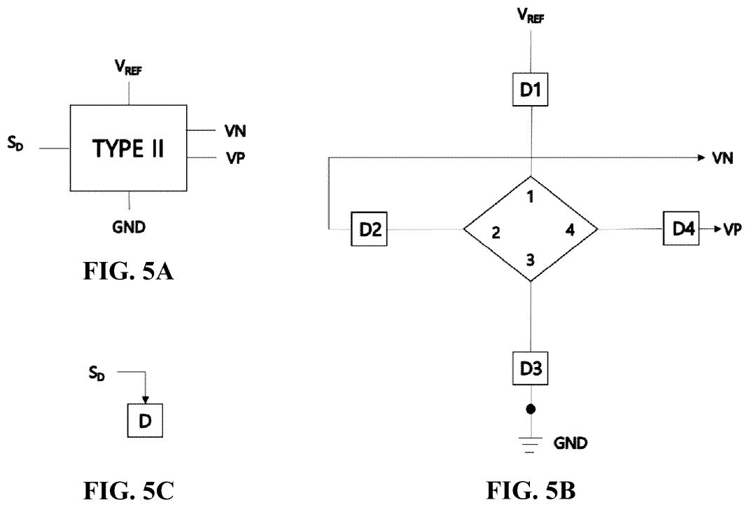

FIGS. 5A to 5C illustrate an embodiment of the second type (TYPE II) of a Hall element module.

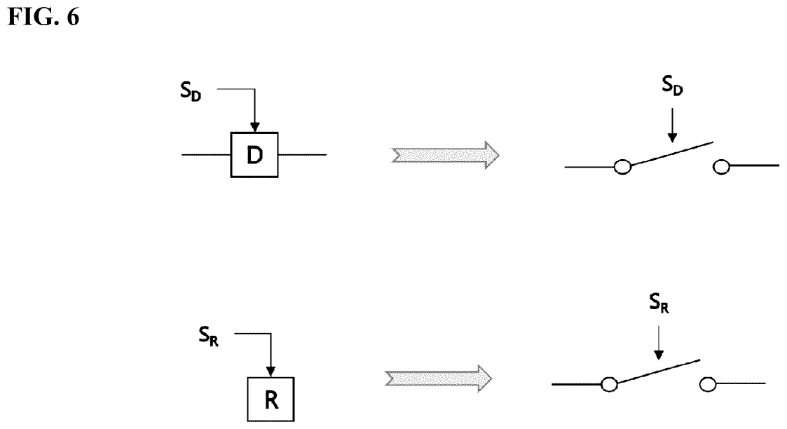

FIG. 6 is an embodiment of a selection unit shown in FIGS. 4A to 4C and 5A to 5C.

The second type (TYPE II) shown in FIGS. 5A to 5C are identical to the first type (TYPE I) shown in FIGS. 4A to 4C, except that the two selection units R that generate the auxiliary voltage for temperature compensation VEN are absent in the first type. Therefore, a configuration of the first type (TYPE I) shown in FIG. 4 will be described below, and this will be applied to the second type (TYPE II) shown in FIG. 5.

Referring to FIGS. 4A to 4C, the first type (TYPE I) generates detection voltages VP and VN and an auxiliary voltage for temperature compensation VEN in response to a magnetic detection control signal SD and a temperature compensation control signal SR (FIG. 4A), includes a Hall element 410 and multiple selection units D and R (FIG. 4B). Among the multiple selection units, the selection unit D for magnetic detection performs a switching operation in response to the magnetic detection control signal SD, and the selection unit R for temperature compensation performs a switching operation in response to the temperature compensation control signal SR (FIG. 4C).

The selection units D and R may be implemented as switches that electrically connect or disconnect both terminals in response to the respective control signals among the magnetic detection control signal SD and the temperature compensation control signal SR. In the description below, it is assumed that when the selection unit is activated or turned on, both terminals are electrically connected, and when the selection unit is deactivated or turned off, both terminals are electrically disconnected.

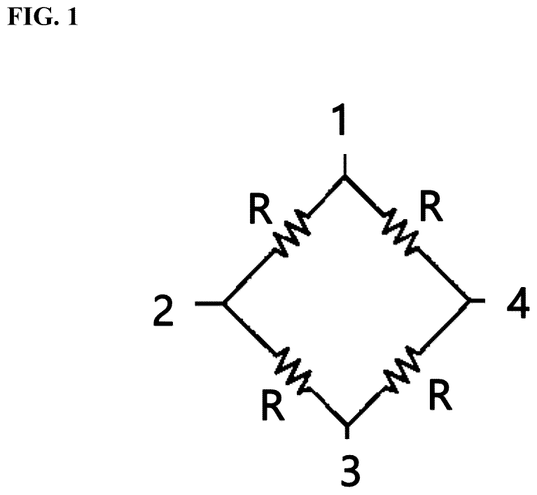

Referring to the equivalent circuit shown in FIG. 1, when a magnetic detection control signal Sp is activated, the four magnetic detection selection units D are turned on to electrically connect both terminals. At this time, a constant current flows inside the Hall element module due to the two voltage sources VREF and GND connected to terminals 1 and 3 of the Hall element module. The magnitude difference of currents flowing through the two paths causes a difference in voltage drop at the two nodes 2 and 4. The voltage dropped at a second node 2 is a VN detection voltage, and the voltage dropped at a fourth node 4 is a VP detection voltage.

Here, one of the two paths, a first path, includes node 1 (1), node 2 (2), and node 3 (3), and the other path, a second path, includes node 1 (1), node 4 (4), and node 3 (3).

In the absence of the influence of an external magnetic field, the magnitude of the current flowing through the first path and the second path is equal, so the voltage level of the voltage VN dropped at node 2 and the voltage level of the voltage VP dropped at node 4 are equal.

In the presence of an external magnetic field, the magnitude of the current flowing through the first path and the second path varies depending on the direction of the magnetic field. Accordingly, the voltage level of the voltage VN dropped at node 2 and the voltage level of the voltage VP dropped at node 4 vary depending on the magnitude and direction of the magnetic field. This difference enables the estimation of the direction and magnitude of the magnetic field.

A Hall element module of the first type (TYPE I) provided in the present invention, which is in an inactive state, generates an auxiliary voltage for temperature compensation VEN to compensate for temperature-induced errors when a Hall element module in an active state detects magnetic intensity. In other words, when one Hall element module measures magnetic intensity, this Hall element module generates a voltage corresponding to the magnitude of current flowing through another Hall element module that performs the same function but is in an inactive state, namely the auxiliary voltage for temperature compensation VEN, and uses this auxiliary voltage for temperature compensation VEN to generate a voltage that may compensate for the detection voltage of the activated Hall element module detecting the magnetic field, namely the reference voltage for temperature compensation ADVR.

The second type (TYPE II) shown in FIG. 5 is identical to the configuration shown in FIG. 4 except that two selection units R are removed, so this type will not be described in detail here.

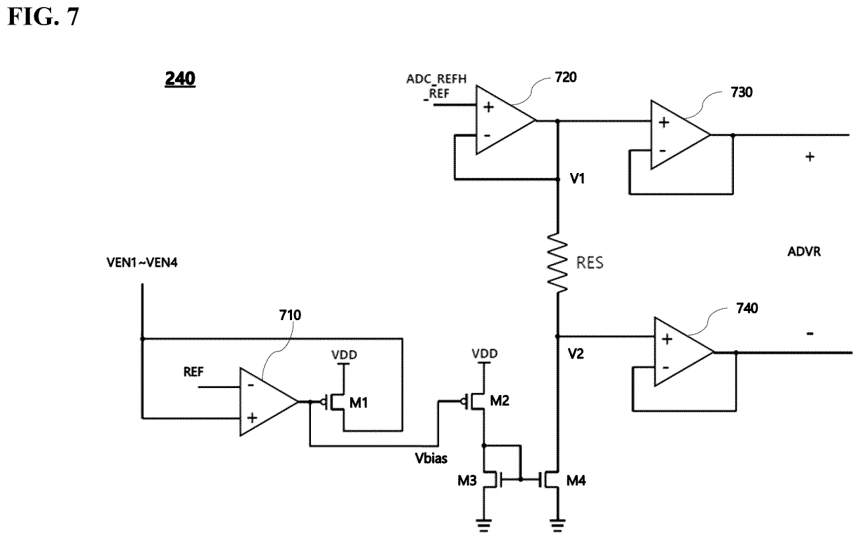

FIG. 7 is an embodiment of a reference voltage generation circuit.

Referring to FIG. 7, the reference voltage generation circuit 240 includes multiple differential amplifiers 710, 720, 730, and 740, multiple transistors M1, M2, N3, and M4, and a resistor RES, and generates a reference voltage for temperature compensation ADVR using the auxiliary voltage for temperature compensation VEN output from the driving part 210.

The operation of the circuit shown in FIG. 7 may be easily understood by those skilled in the art, so this operation will not be described in detail here. However, a brief description is provided below to facilitate understanding of the operation of the circuit.

A first differential amplifier 710 amplifies the differential voltage between a comparison reference voltage REF and an auxiliary voltage for temperature compensation VEN to generate a bias voltage Vbias. The auxiliary voltage for temperature compensation VEN1~VEN4

The bias voltage Vbias is applied to a gate terminal of a first MOS transistor MI to determine the magnitude of current flowing from a power supply voltage VDD to the auxiliary voltage for temperature compensation VEN through the first MOS transistor M1, which performs a negative feedback function that changes the voltage level of the auxiliary voltage for temperature compensation VEN.

The first differential amplifier 710 and the first MOS transistor M1 amplify the differential voltage between the comparison reference voltage REF and the auxiliary voltage for temperature compensation VEN to generate a stabilized bias voltage Vbias.

The bias voltage Vbias determines the magnitude of current flowing through a second MOS transistor M2, and the current flowing through the second MOS transistor M2 determines the magnitude of current flowing through a third MOS transistor M3 and a fourth MOS transistor M4, which form a current mirror. The voltage level at one terminal of the fourth MOS transistor M4, namely a voltage level of a first output voltage V1, is determined by current flowing through the fourth MOS transistor M4.

A second differential amplifier 720 forms a buffer in which a negative input terminal is connected to an output terminal and a reference voltage for temperature compensation ADC_REFH_REF is applied to a positive input terminal, and generates the first output voltage V1.

The resistor for temperature compensation reference RES is installed between the first output voltage V1 and the second output voltage V2 to change the difference voltage between the first output voltage V1 and the second output voltage V2 according to temperature changes.

A third differential amplifier 730 and a fourth differential amplifier 740 buffer the first output voltage V1 and the second output voltage V2, respectively, and the difference between the output voltages of the third differential amplifier 730 and the fourth differential amplifier 740 becomes the reference voltage for temperature compensation ADVR.

Referring to FIG. 2, the reference voltage for temperature compensation ADVR is utilized when the AD converter 230 converts the analog differential amplified detection voltage VIN into the digital signal (Data), thereby minimizing temperature-induced deviations in the detected electric field quantity.

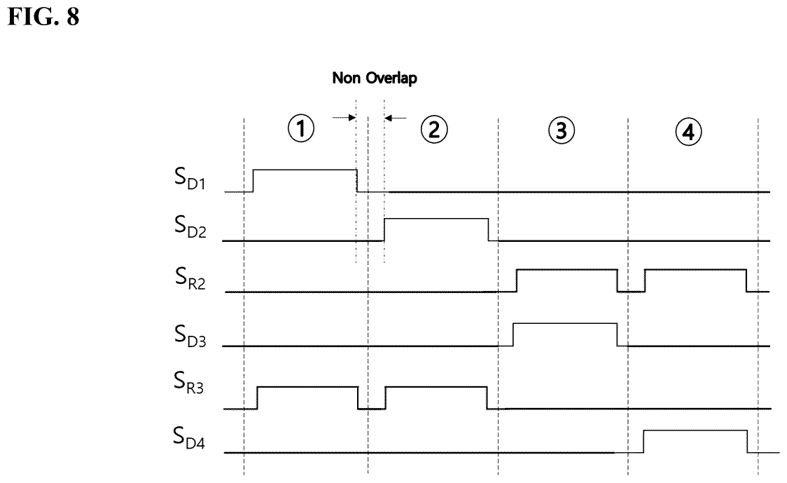

FIG. 8 is a timing diagram of control signals applied to a magnetic sensor according to the present invention.

Referring to FIG. 8, the magnetic sensor 200 may use six control signals SD₁, SD₂, SR₂, SD₃, SR₃, and SD₄. SD and SR of the control signals indicate the magnetic detection control signal and the temperature compensation control signal, respectively, and the Arabic numerals correspond to the numbers of the Hall element modules.

Referring to FIG. 8, it may be seen that when the first Hall element module \textcircled{1} detects external magnetism, a first magnetic detection control signal SD₁ and a third temperature compensation control signal SR₃ are activated, and the remaining four control signals SD₂, SR₂, SD₃, and SD₄ are in an inactive state.

Similarly, it may be seen that when the second Hall element module \textcircled{2} detects external magnetism, a second magnetic detection control signal SD₂ and a third temperature compensation control signal SR₃ are activated, and the remaining four control signals SD₁, SR₂, SD₃, and SD₄ are in an inactive state.

The description of when the third and fourth Hall element modules \textcircled{3} and \textcircled{4} detect external magnetism is replaced with the description above.

It is preferred that the active periods of the magnetic detection control signal S_{D} and the temperature compensation control signal S_{R} do not overlap with each other when applied to different Hall element modules.

For example, referring to FIG. 8, it may be seen that when the magnetic detection control signal S_{D1} drives the first Hall element module \textcircled{1} and when the magnetic detection control signal S_{D2} drives the second Hall element module \textcircled{2}, their active periods do not overlap with each other (Non Overlap).

It is preferred that the consecutively operating temperature compensation control signals S_{R} have active periods that do not overlap with each other, similar to the magnetic detection control signal S_{D1}.

Although FIG. 3 illustrates each Hall element module as including a single Hall element 410, embodiments including two or more Hall elements 410 may also be provided as described below.

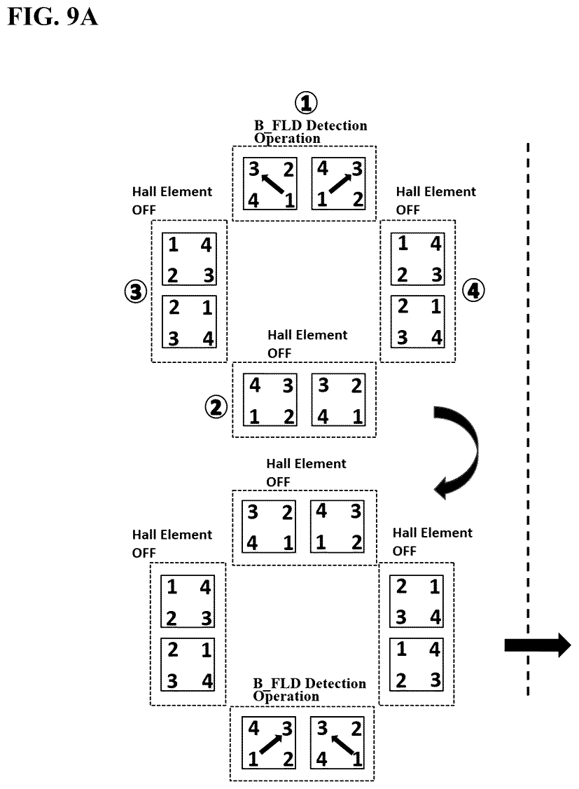

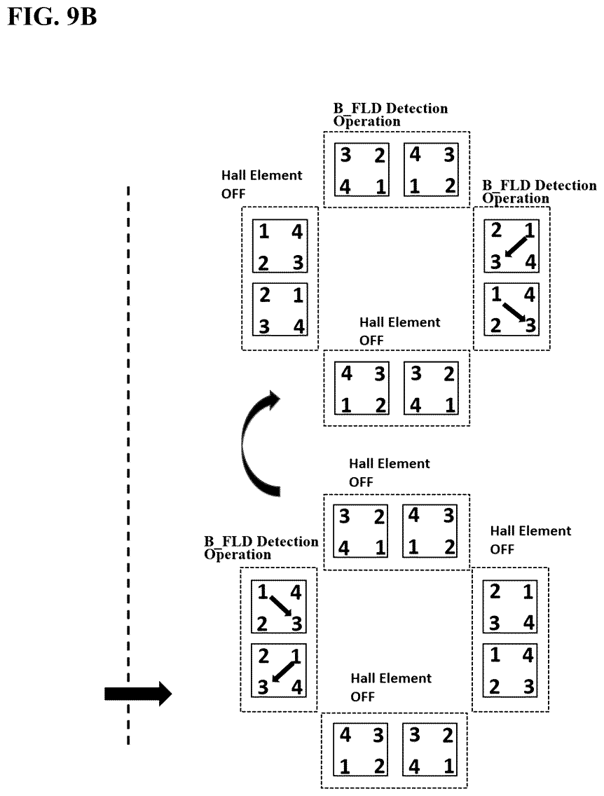

FIGS. 9A and 9B illustrate a configuration and magnetic sensing process of a magnetic sensor according to the present invention, which includes Hall element modules, each including two Hall elements.

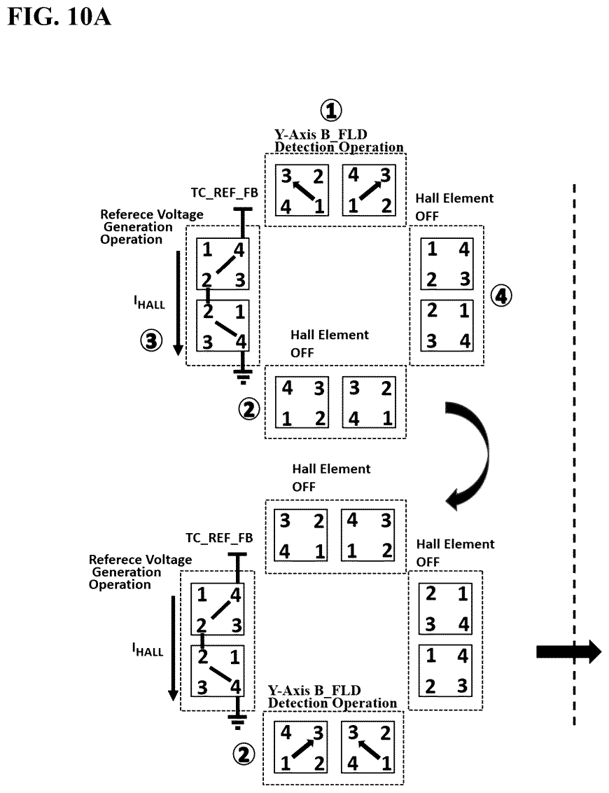

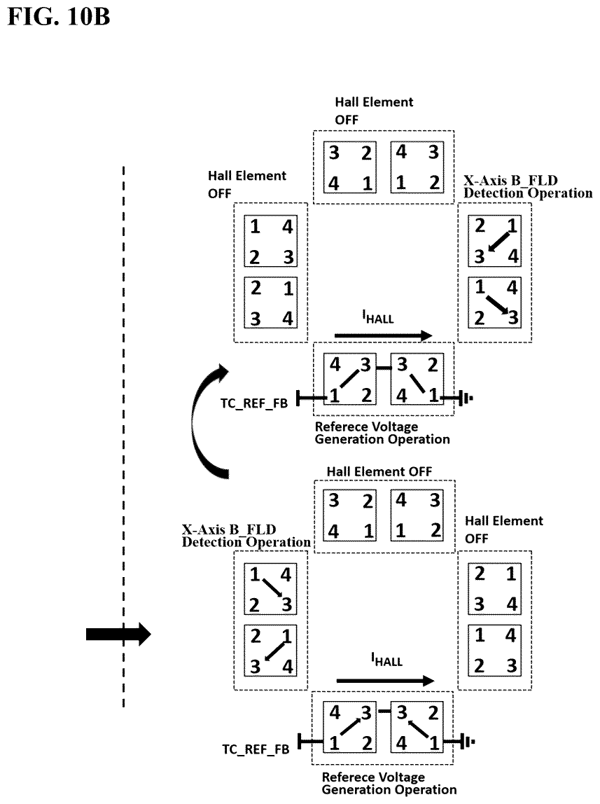

FIGS. 10A and 10B are an example of a Hall element module used in a sensing process of a magnetic sensor and in a generation process of a temperature compensation voltage.

Referring to FIGS. 9A, 9B, 10A, and 10B, the magnetic sensor including two Hall elements may also detect magnetism in the same sequence as the embodiment illustrated in FIG. 3. In addition, when one Hall element module detects external magnetism, selecting one of the remaining three Hall element modules to generate an auxiliary voltage for temperature compensation VEN1 to VEN4, which is used to generate a temperature compensation reference voltage ADVR, is the same.

### INDUSTRIAL APPLICABILITY

The present invention relates to a magnetic sensor, which can be used throughout various industries, such as being used for terrain education for the visually impaired, detecting defects in the inner walls of hollow structures, and detecting crane positions.

What is claimed is:

1. A magnetic sensor comprising:
a Hall driving part including a first-type Hall element module configured to generate two detection voltages corresponding to a direction and magnitude of magnetism (hereinafter referred to as magnetic intensity) measured in response to a magnetic detection control signal and a temperature compensation control signal and to generate an auxiliary voltage for temperature compensation in response to the temperature compensation control signal, and a second-type Hall element module configured to generate two detection voltages corresponding to the measured magnetic intensity;
an amplifier configured to amplify a difference between the two detection voltages;
an AD converter configured to convert an analog differential amplified detection voltage, amplified by the amplifier, into a digital signal using a reference voltage for temperature compensation; and
a reference voltage generation circuit configured to generate the reference voltage for temperature compensation using the auxiliary voltage for temperature compensation.

2. The magnetic sensor of claim 1, wherein the Hall driving part includes two first-type Hall element modules and two second-type Hall element modules.

3. The magnetic sensor of claim 2, wherein the Hall driving part has the two first-type Hall element modules and the two second-type Hall element modules respectively disposed at vertex positions of an imaginary square.

4. The magnetic sensor of claim 3, wherein the Hall driving part is configured such that when one Hall element module among the two first-type Hall element modules and the two second-type Hall element modules generates the two detection voltages, one Hall element module among the two first-type Hall element modules generates the reference voltage for temperature compensation, and the remaining Hall element modules do not perform operations according to functions.

5. The magnetic sensor of claim 1, wherein the first-type Hall element module includes:
a Hall element including a second node and a fourth node that generate voltages corresponding to magnetic intensity, and a first node and a third node to which voltage is supplied;
a 1-1 detection process selection unit that switches a power supply voltage to the first node in response to the magnetic detection control signal;
a 2-1 detection process selection unit that switches a voltage of the second node to one of the two detection voltages in response to the magnetic detection control signal;
a 3-1 detection process selection unit that switches the third node to ground power in response to the magnetic detection control signal;
a 4-1 detection process selection unit that switches a voltage of the fourth node to the remaining one of the two detection voltages in response to the magnetic detection control signal;
a first temperature compensation process selection unit that switches the second node to the auxiliary voltage for temperature compensation in response to the temperature compensation control signal; and
a second temperature compensation process selection unit that switches the fourth node to ground power in response to the temperature compensation control signal.

6. The magnetic sensor of claim 5, wherein the second-type Hall element module includes:
a Hall element including a second node and a fourth node that generate voltages corresponding to magnetic intensity, and a first node and a third node to which voltage is supplied;
a 1-2 detection process selection unit that switches a power supply voltage to the first node in response to the magnetic detection control signal;
a 2-2 detection process selection unit that switches a voltage of the second node to one of the two detection voltages in response to the magnetic detection control signal;
a 3-2 detection process selection unit that switches the third node to ground power in response to the magnetic detection control signal; and
a 4-2 detection process selection unit that switches a voltage of the fourth node to the remaining one of the two detection voltages in response to the magnetic detection control signal.

7. The magnetic sensor of claim 4, further comprising:
a control signal generation circuit that generates a magnetic detection control signal and a temperature compensation control signal.

8. The magnetic sensor of claim 7, wherein the magnetic detection control signal exclusively drives the two first-type Hall element modules and the two second-type Hall element modules, and
the temperature compensation control signal exclusively drives the two first-type Hall element modules.

9. The magnetic sensor of claim 8, wherein the magnetic detection control signals applied to different Hall element modules have active periods that do not overlap with each other, and
the temperature compensation control signals applied to different Hall element modules have active periods that do not overlap with each other.

10. The magnetic sensor of claim 1, wherein the Hall driving part includes two pairs of first-type Hall element modules, wherein the first type hall element modules are connected in series, and includes two pairs of the second-type Hall element modules, wherein the second-type Hall element modules are connected in series.

11. The magnetic sensor of claim 10, wherein the Hall driving part has the two pairs of first-type Hall element modules and the two pairs of second-type Hall element modules respectively disposed at vertex positions of an imaginary square.
